(19) United States
(12) Patent Application Publication
(10) Pub. No.: US 2024/0071761 A1
(43) Pub. Date: Feb. 29, 2024

(54) SEMICONDUTOR STRUCTURE AND MANUFACTURING METHOD THEREOF

(71) Applicant: ENKRIS SEMICONDUCTOR, INC., Suzhou (CN)

(72) Inventor: Kai Cheng, Suzhou (CN)

(73) Assignee: ENKRIS SEMICONDUCTOR, INC., Suzhou (CN)

(21) Appl. No.: 18/356,211

(22) Filed: Jul. 20, 2023

(30) Foreign Application Priority Data
Aug. 25, 2022 (CN) 202211028465.9

(51) Int. Cl. H01L 21/02; C30B 25/04; C30B 29/68

(52) U.S. Cl. CPC H01L 21/02639; C30B 25/04; C30B 29/68; H01L 21/0254; H01L 21/02642; H01L 21/02645; H01L 21/02647; H01L 21/02378; H01L 21/02381; H01L 21/0242; H01L 21/02458

(57) ABSTRACT

In the present disclosure, a semiconductor structure and a manufacturing method of the semiconductor structure are provided. The semiconductor structure includes a base, a first mask layer, a first epitaxial layer, and a second epitaxial layer. The first mask layer is located on the base, and the first mask layer has a first window that exposes the base. The first window includes an opening end far from the base and a bottom wall end close to the base. On the plane where the base is located, the orthographic projection of the opening end falls within the bottom wall end.

### CROSS REFERENCE TO RELATED APPLICATIONS

This application claims priority to Chinese Patent Application No. 202211028465.9 filed on Aug. 25, 2022, the entire content of which is incorporated herein by reference.

### TECHNICAL FIELD

This present disclosure relates to the field of semiconductor, and more particular, to a semiconductor structure and a method of manufacturing the semiconductor structure.

### BACKGROUND

Gallium nitride (GaN) is the third generation new semiconductor material after the first and second generation semiconductor materials such as Si and GaAs. As a wide band gap semiconductor material, GaN has many advantages, such as high saturation drift velocity, high breakdown voltage, excellent carrier transport properties, and the ability to form ternary alloys, like AlGaN and InGaN, and quaternary alloys, like AlInGaN. In addition, GaN is easy to make GaN-based PN junction. In view of this, extensive and in-depth researches have conducted on GaN-based materials and GaN-based semiconductor devices in recent years, and the growth of GaN-based materials by using MOCVD (Metal Organic Chemical Vapor Deposition) technology is becoming more and more mature. In the field of semiconductor device research, significant achievements and significant development have been made in optoelectronic devices such as GaN-based LEDs (light-emitting devices) and LDs (laser diodes), as well as microelectronic devices such as GaN-based HEMTs (High electron mobility transistors).

With the more applications of GaN-based materials in power devices/display devices, the demand for dislocation density of GaN-based materials in terminal products has further increased. According to the traditional mode, the dislocation surface density of GaN-based materials grown by using mainstream MOCVD epitaxial equipment on a mainstream epitaxial base of aluminum trioxide (Al₂O₃) is in a range from 1E8/cm\hat{ }3 to 3E8/cm\hat{ }3. In order to manufacture GaN-based power devices that can withstand higher voltage and GaN-based LEDs with longer wavelengths, it is necessary to further reduce the dislocation density of GaN-based materials.

In view of this, it is necessary to provide a new semiconductor structure and a method of manufacturing the new semiconductor so as to meet the above demands.

### SUMMARY

A semiconductor structure and a manufacturing method of the semiconductor structure are provided in the present disclosure.

According to a first aspect of the present disclosure, a semiconductor structure is provided, the semiconductor structure includes: a base; a first mask layer, located on the base; where the first mask layer has a first window exposing the base, wherein the first window includes an opening end away from the base and a bottom wall end close to the base; and an orthographic projection of the opening end on a plane where the base is located falls within an orthographic projection of the bottom wall end.

In some embodiments, an area of a cross-section of the first window gradually decreases in a direction from the base to the opening end.

In some embodiments, a cross-section of the first window perpendicular to the plane where the base is located is enclosed by a first side, a second side, a third side, and a fourth side connected sequentially; the first side corresponds to the opening end, and the third side corresponds to the bottom wall end, the second side and the fourth side correspond to the sidewalls of the first window, the second side includes a straight line or a curve, and the fourth side includes a straight line or a curve.

In some embodiments, the first mask layer includes a first sub-mask layer close to the base and a second sub-mask layer far from the base, wherein the first sub-mask layer has a first sub-window, and the second sub-mask layer has a second sub-window, the second sub-window and the first sub-window are interconnected and form at least a part of the first window; an area of the orthographic projection of the second sub-window on a plane where the base is located is smaller than an area of the orthographic projection of the first sub-window on a plane where the base is located.

In some embodiments, the semiconductor structure further includes a second mask layer, where the second mask layer includes a first region, and the first region is located on a part of the bottom wall end.

In some embodiments, an orthographic projection of the first region on the plane where the base is located at least partially overlaps with an orthographic projection of the opening end on the plane where the base is located.

In some embodiments, the second mask layer further includes a second region, and the second region is located on the first mask layer.

In some embodiments, the semiconductor structure further includes: a first epitaxial layer, filling up the first window; and a second epitaxial layer located on the first epitaxial layer and the first mask layer.

In some embodiments the first epitaxial layer includes a first sub-epitaxial layer and a second sub-epitaxial layer, where the first sub-epitaxial layer is located on the bottom wall end and fills a partial depth of the first window; the semiconductor structure further includes a third mask layer, which includes a third region, the third region is located on a part of the first sub-epitaxial layer; the second sub-epitaxial layer is located on the first sub-epitaxial layer and the third region.

In some embodiments, an orthographic projection of the third region on the plane where the base is located at least partially overlaps with an orthographic projection of the opening end on the plane where the base is located.

In some embodiments, the third mask layer further includes a fourth region; the fourth region is located on the first mask layer; and the second epitaxial layer is located on the first epitaxial layer and the fourth region of the third mask layer.

In some embodiments, the semiconductor structure further includes: a first epitaxial layer, filling up the first window; a second epitaxial layer, located on the first epitaxial layer and the first mask layer; the second epitaxial layer includes a third sub-epitaxial layer and a fourth sub-epitaxial layer; the third sub-epitaxial layer is located on the first epitaxial layer and the first mask layer; the semiconductor structure further includes a fourth mask layer located on the third sub-epitaxial layer; the orthographic projection of the opening end of the first window on the plane where the base is located falls within an orthographic projection of the fourth mask layer on the plane where the base is located; the fourth sub-epitaxial layer is located on the third sub-epitaxial layer and the fourth mask layer.

In some embodiments, there are a plurality of first windows, and second epitaxial layers corresponding to respective the plurality of the first windows are combined into a plane.

According to a second aspect of the present disclosure, a manufacturing method of a semiconductor structure is provided, the manufacturing method includes: providing a base, and forming a first mask layer on the base, where the first mask layer has a first window exposing the base; the first window includes an opening end far from the base and a bottom wall end close to the base; and on a plane where the base is located, an orthographic projection of the opening end falls within an orthographic projection of the bottom wall end.

In some embodiments, forming the first mask layer on the base, includes: forming a first occupying material layer on the base; patterning the first occupying material layer by an etching process to form a first occupying layer; where, in a direction from the base to the first occupying layer, an area of a cross-section of the first occupying layer gradually decreases; forming a first mask material layer on the first occupying layer and the base; polishing the first mask material layer until the first occupying layer is exposed, such that the first mask material layer becomes the first mask layer; removing the first occupying layer to form the first window within the first mask layer.

In some embodiments, forming the first mask layer on the base, includes: forming at least a first sub-mask material layer and a second sub-mask material layer sequentially on the base; etching the second sub-mask material layer to form a second sub-window, where an etching rate of the second sub-mask material layer is lower than an etching rate of the first sub-mask material layer; and laterally etching the first sub-mask material layer through the second sub-window to form a first sub-window, where the second sub-window and the first sub-window form at least a part of the first window.

In some embodiments, the manufacturing method further includes before forming the first mask layer, depositing a second mask layer, where the second mask layer includes a first region, and the first region located on a part of the bottom wall end.

In some embodiments, the manufacturing method further includes an epitaxial growth process; the epitaxial growth process is performed on the base with the first mask layer as a mask, to sequentially form a first epitaxial layer and a second epitaxial layer, where the first epitaxial layer is epitaxial grown from the bottom wall end to fill up the first window, and the second epitaxial layer is epitaxial grown on the first epitaxial layer and the first mask layer.

Compared with the prior art, the present disclosure has the following beneficial effects:

Semiconductor structures can be used for manufacturing GaN-based semiconductor devices by an epitaxial growth process. A base with a first mask layer is used as the base for epitaxial growth of GaN-based materials. On the plane where the base is located, the orthographic projection of the opening end of the first window in the first mask layer falls within the bottom wall end. The inward first window is used to terminate the dislocation density of the GaN-based material, thereby when the GaN-based material continues to epitaxially grow, the dislocation density of the GaN-based material is reduced. In addition, with a large size of the bottom wall end, the nucleation area of GaN-based materials is large, which makes the growth process easier.

### BRIEF DESCRIPTION OF DRAWINGS

FIG. 1 is a cross-sectional schematic diagram of a semiconductor structure according to a first embodiment of the present disclosure.

FIG. 2 is a cross-sectional schematic diagram of another semiconductor structure according to the first embodiment.

FIG. 3 is a flowchart of a manufacturing method of the semiconductor structure of FIG. 1.

FIGS. 4 to 7 are schematic views illustrating intermediate structures corresponding to the process of FIG. 3.

FIG. 8 is a top view schematic diagram of a structure of a base and a first mask layer in FIG. 1.

FIG. 9 is a cross-sectional schematic diagram of the semiconductor structure according to a second embodiment of the present disclosure.

FIG. 10 is a cross-sectional schematic diagram of a structure of a base and a first mask layer in FIG. 9.

FIG. 11 is a cross-sectional schematic diagram of a semiconductor structure according to a third embodiment of the present disclosure.

FIG. 12 is a cross-sectional schematic diagram of a structure of a base and a first mask layer in FIG. 11.

FIG. 13 is a schematic view of an intermediate structure corresponding to a manufacturing method of a semiconductor structure according to the third embodiment of the present disclosure.

FIG. 14 is a cross-sectional schematic diagram of a semiconductor structure according to a fourth embodiment of the present disclosure.

FIG. 15 is a cross-sectional schematic diagram of a structure of a base and a first mask layer in FIG. 14.

FIG. 16 is a cross-sectional schematic diagram of a semiconductor structure according to a fifth embodiment of the present disclosure.

FIG. 17 is a cross-sectional schematic diagram of a structure of a base and a first mask layer in FIG. 16.

FIG. 18 is a cross-sectional schematic diagram of a semiconductor structure according to a sixth embodiment of the present disclosure.

FIG. 19 is a cross-sectional schematic diagram of a structure of a base and a first mask layer in FIG. 18.

FIG. 20 is a cross-sectional schematic diagram of a semiconductor structure according to a seventh embodiment of the present disclosure.

FIG. 21 is a cross-sectional schematic diagram of a semiconductor structure according to an eighth embodiment of the present disclosure.

FIG. 22 is a cross-sectional schematic diagram of a semiconductor structure according to a ninth embodiment of the present disclosure.

FIG. 23 is a schematic view of an intermediate structure corresponding to a manufacturing method of a semiconductor structure according to the ninth embodiment of the present disclosure.

FIG. 24 is a cross-sectional schematic diagram of the semiconductor structure according to a tenth embodiment of the present disclosure.

FIG. 25 is a cross-sectional schematic diagram of a structure of a base and a first mask layer in FIG. 24.

FIG. 26 is a top view schematic diagram of a structure of a base and a first mask layer in FIG. 24.

FIG. 27 is a cross-sectional schematic diagram of the semiconductor structure according to an eleventh embodiment of the present disclosure.

To facilitate the understanding of the present disclosure, all reference signs present in the present disclosure are listed below:

| | |
|---|---|
| semiconductor structure 1, 2, 3, 4, 5, 6, | base 10 |
| 7, 8, 9, 20, 21 | |
| semiconductor substrate 100 | transition layer 101 |
| first mask layer 11 | first window 110 |
| opening end 110a | bottom wall end 110b |
| second side 110c | fourth side 110d |
| first angle α | second angle β |
| first epitaxial layer 12 | first sub-epitaxial layer 121 |
| second sub-epitaxial layer 122 | second epitaxial layer 13 |
| third sub-epitaxial layer 131 | fourth sub-epitaxial layer 132 |
| first mask material layer 11′ | first sub-mask layer 111 |
| first sub-mask material layer 111′ | first sub-window 1101 |
| second sub-mask layer 112 | second sub-mask material layer |
| | 112′ |
| second sub-window 1102 | third sub-mask layer 113 |
| third sub-window 1103 | second mask layer 14 |
| first region 141 | second region 142 |
| third mask layer 15 | third region 151 |
| fourth region 152 | fourth mask layer 16 |
| first occupying layer 31 | first occupying material layer |
| | 31′ |
| fifth side 31a | sixth side 31b |
| seventh side 31c | eighth side 31d |
| fourth mask material layer 16′ | |

### DETAILED DESCRIPTION

In order to make the above-mentioned objects, features and advantages of the present disclosure more obvious and understandable, embodiments of the present disclosure will be described in detail below with reference to the accompanying drawings.

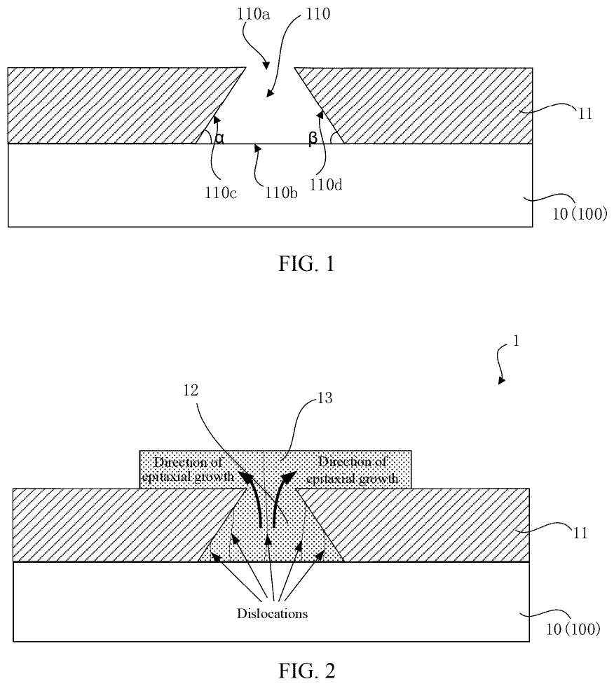

FIG. 1 is a cross-sectional schematic diagram of a semiconductor structure according to a first embodiment of the present disclosure; FIG. 2 is a cross-sectional schematic diagram of another semiconductor structure according to the first embodiment.

Referring to FIGS. 1 and 2, in an embodiment of the present disclosure, a semiconductor structure 1 is provided. The semiconductor structure 1 includes: a base 10; a first mask layer 11 on the base 10. The first mask layer 11 has a first window 110 that exposes the base 10. The first window 110 includes an opening end 110a away from the base 10 and a bottom wall end 110b close to the base 10. An orthographic projection of the opening end 110a on the plane where the base 10 is located falls within the bottom wall end 110b.

In this embodiment, the base 10 is a multi-layer structure. The base 10 includes, for example, a semiconductor substrate 100 and a nucleation layer located on the semiconductor substrate 100 (not shown in FIG. 1). The material of the semiconductor substrate 100 can include at least one of sapphire, silicon carbide, and monocrystalline silicon, and the material of the nucleation layer can include AN.

In other embodiments, the base 10 can be a single-layer structure, such as the semiconductor substrate 100. The material of the semiconductor substrate 100 can include silicon carbide or gallium nitride, etc.

The material of the first mask layer 11 can include at least one of silicon dioxide and silicon nitride. In this embodiment, the first mask layer 11 is a single-layer structure. In other embodiments, the first mask layer 11 can be a multi-layer structure, including at least two different material layers.

In this embodiment, there is one first window 110, and the vertical section of the first window 110 is a regular trapezoid, where the vertical section indicates a section perpendicular to the plane in which the base 10 is located. Specifically, a regular trapezoid is enclosed by four sides: the first side, second side 110c, third side, and fourth side 110d, where the first side corresponds to the opening end 110a and the third side corresponds to the bottom wall end 110b. The second side 110c and fourth side 110d correspond to the side walls of the first window 110. The second side 110c and fourth side 110d are straight lines.

The cross-section of the first window 110 can include rectangular, triangular, hexagonal, circle or other shapes. The cross-section indicates a section parallel to the plane in which the base 10 is located.

In some embodiments, as shown in FIG. 2, the semiconductor structure 1 further includes: a first epitaxial layer 12, filling up the first window 110; a second epitaxial layer 13, located on the first epitaxial layer 12 and the first mask layer 11. The semiconductor structure can be used for an epitaxial growth process during manufacturing a semiconductor device, and the semiconductor device can include GaN-based materials.

An angle between the second side 110c and the base 10 exposed by the first window 110 refers to a first angle α, and the first angle α is an acute angle; an angle between the fourth side 110d and the base 10 exposed by the first window 110 refers to a second angle β, and the second angle β is an acute angle; and the first angle α and the second angle β can be equal or not. The advantage is that when the dislocations of the first epitaxial layer 12 grown in the first window 110 are along a thickness direction of the first mask layer 11 or have an angle with the thickness direction, the smaller the first angle α and the second angle β, the larger the area of the sidewall that can terminate the extension of dislocations, and therefore the termination effect can be better. For example, when the material of the first epitaxial layer 12 includes GaN, the dislocations of GaN are mainly linear dislocations in the crystal orientation, that is, linear dislocations extending along the thickness direction of the first mask layer 11. At this time, the smaller the first angle α and the second angle β, the larger the area of the sidewall that can terminate the extension of dislocations, and therefore the termination effect can be better. Reducing the dislocation density of the first epitaxial layer 12 can reduce the dislocation density of the second epitaxial layer 13.

The first epitaxial layer 12 and the second epitaxial layer 13 can include the same material, for example can both include GaN-based materials, such as at least one of GaN, AlGaN, InGaN, and AlInGaN, which is not limited in this embodiment.

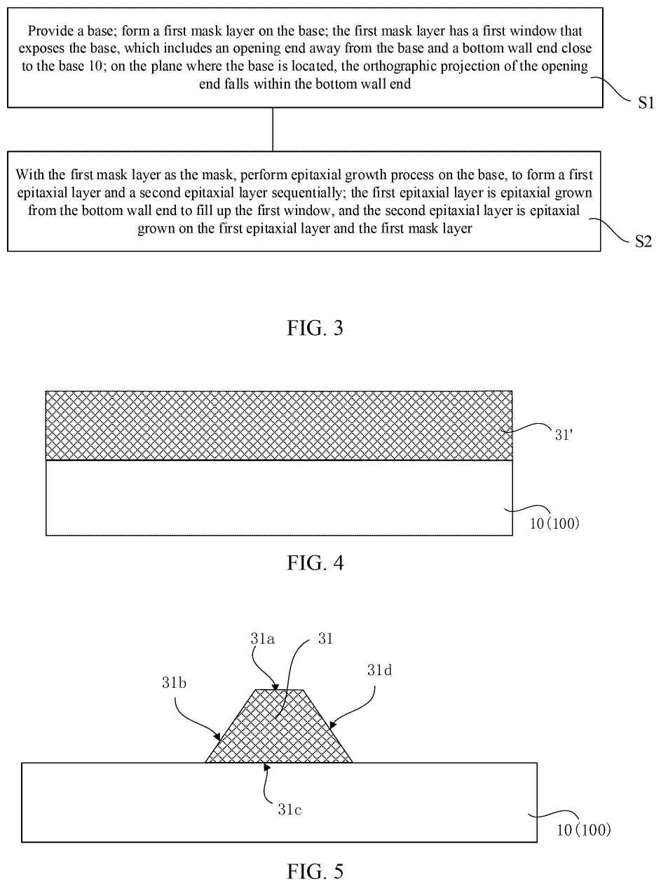

A manufacturing method of the semiconductor structure of FIG. 1 is provided in this present disclosure. FIG. 3 is a flowchart of a manufacturing method of the semiconductor structure of FIG. 1; FIGS. 4 to 7 are schematic views illustrating intermediate structures corresponding to the process of FIG. 3.

First of all, referring to step S1 in FIG. 3 and FIG. 1, a base 10 is provided, a first mask layer 11 is formed on the base 10. The first mask layer 11 has a first window 110 that exposes the base 10, which includes an opening end 110a away from the base 10 and a bottom wall end 110b close to the base 10. On the plane where the base 10 is located, the orthographic projection of the opening end 110a falls within the bottom wall end 110b.

In this embodiment, step S1 can include steps S11 to S13. At step S11, as shown in FIG. 4, a first occupying material layer 31′ is formed on the base 10; as shown in FIG. 5, the first occupying material layer 31′ is patterned by an etching process to form the first occupying layer 31. In the direction from the base 10 to the first occupying layer 31, an area of the cross-section of the first occupying layer 31 gradually decreases.

In some embodiments, the cross-section of the first occupying layer 31 perpendicular to the plane where the base 10 is located is enclosed by four sides, a fifth side 31a, a sixth side 31b, a seventh side 31c, and an eighth side 31d. The fifth side 31a far from the base 10, the seventh side 31c located on the base 10, and the sixth side 31b and the eighth side 31d are straight lines. The material of the first occupying material layer 31′ can include silicon dioxide, formed by physical vapor deposition or chemical vapor deposition. The patterning of the first occupying material layer 31′ can be achieved by dry etching or wet etching.

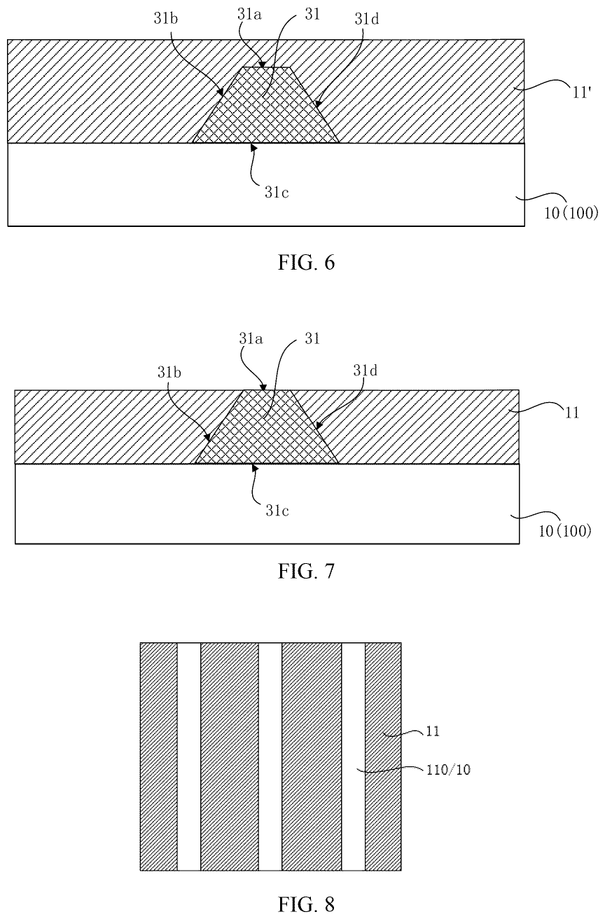

At step S12, as shown in FIG. 6, a first mask material layer 11′ is formed on the first occupying layer 31 and the base 10; as shown in FIG. 7, the first mask material layer 11′ is polished until the first occupying layer 31 is exposed, and at this time, the first mask material layer 11′ becomes the first mask layer 11.

In this embodiment, the first mask material layer 11′ is a single-layer structure. A single-layer structure can be formed by using one process or multiple processes. In other embodiments, the first mask material layer 11′ can also be a multi-layer structure, including at least two different material layers, which are formed by multiple processes.

The material of the first mask material layer 11′ can include silicon dioxide, formed by physical vapor deposition or chemical vapor deposition. The polishing of the first mask material layer 11′ can be achieved by using the Chemical Mechanical Grinding (CMP) method.

At step S13, as shown in FIGS. 7 and 1, the first occupying layer 31 is removed to form a first window 110 within the first mask layer 11.

The first occupying layer 31 can be removed by wet etching, such as using hydrofluoric acid. It should be noted that when removing the first occupying layer 31, the material of the first occupying layer 31 is different from that of the first mask layer 11. The etching solution used for wet etching has a higher corrosion rate on the first occupying layer 31 than on the first mask layer 11, thereby allowing the first occupying layer 31 to be removed firstly and the first mask layer 11 to be retained.

In some embodiments, the step of forming a first mask layer 11 on the base 10 includes: a first mask material layer 11′ is formed on the base 10, where the content of aluminum element of the first mask material layer 11′ is gradually increased in the direction from the base 10 to the first mask material layer 11′; and the first mask material layer 11′ is etched to form the first window 110, such that the first mask material layer 11′ becomes the first mask layer 11. As shown in FIG. 1, the material of the first mask material layer 11′ can include silicon oxide, and the content of aluminum element gradually increases from bottom to top. The etching speed is negatively correlated with the content of aluminum element. Therefore, in the region of the first mask material layer 11′ close to the base 10, the etching speed is faster, so that in the formed first window 110, the area of the bottom wall end 110b is larger than the area of the opening end 110a. In some embodiments, the gradual increase in content of aluminum element may be linear, stepwise, etc., which is not limited in the present disclosure.

In some embodiments, the step of forming a first mask layer 11 on the base 10 includes: a first mask material layer 11′ is formed on the base 10, the first mask material layer 11′ is etched by a dry etching process, and a first window 110 is formed by controlling the etching direction, such that the first mask material layer 11′ becomes a first mask layer 11, where an angle between the etching direction and the direction from the base 10 to the first mask material layer 11′ is an acute angle. Specifically, FIG. 8 is a top view schematic diagram of a structure of a base and a first mask layer in FIG. 1. As shown in FIG. 8, the projection of the first window 110 on the base 10 is presented in strip-shape. The two relatively parallel sides in the presented strip-shape correspond to the projection of the side walls of the second side 110c and the fourth side 110d on the base 10, and the cross-section of the first window 110 perpendicular to the plane where the base 10 is located is a regular trapezoid. Such first window 110 is manufactured with a dry etching process in which the etching direction is controlled by two times. As shown in FIG. 1, the angle between the first etching direction and the plane where the base 10 is located is controlled to be α, to obtain a window with a parallelogram cross-section including the second side 110c and the angle of a. Then, above the window 110, the angle between the second etching direction and the plane where the base 10 is located is controlled to be β, to finally obtain the first window 110 with the trapezoidal cross-section of which the angle between the second side 110c and the base 10 is a and the angle between the fourth side 110d and the base 10 is β. It should be noted that, in FIG. 8, the base 10 is exposed at the first windows 110.

Next, referring to steps S2 in FIG. 3 and FIG. 2, by using the first mask layer 11 as the mask, an epitaxial growth process is performed on the base 10, to form a first epitaxial layer 12 and a second epitaxial layer 13 sequentially. The first epitaxial layer 12 is epitaxial grown from the bottom wall end 110b to fill up the first window 110, and the second epitaxial layer 13 is epitaxial grown on the first epitaxial layer 12 and the first mask layer 11.

The process for forming the first epitaxial layer 12 and the second epitaxial 13 may include: Atomic Layer Deposition (ALD), or Chemical Vapor Deposition (CVD), or molecular beam epitaxial (MBE), or Plasma Enhanced Chemical Vapor Deposition (PECVD), or Low Pressure Chemical Vapor Deposition (LPCVD), or Metal-Organic Chemical Vapor Deposition (MOCVD), or a combination thereof.

The first epitaxial layer 12 and the second epitaxial layer 13 can include the same material, for example can both include GaN-based materials, such as at least one of GaN, AlGaN, InGaN, and AlInGaN. The dislocations in GaN-based materials are along a direction of the thickness of the first mask layer 11 or have an angle with the direction of the thickness. The orthographic projection of the opening end 110a of the first window 110 on the plane where the base 10 is located is within the bottom wall end 110b, which indicates that in the direction from the bottom wall end 110b towards the opening end 110a, the first window 110 has an inward sidewall. The inward sidewall of the first window 110 can terminate at least some of the dislocations in the first epitaxial layer 12, preventing the dislocations from continuing to extend in the second epitaxial layer 13. Therefore, the base 10 with the first mask layer 11 can reduce the dislocation density of the first epitaxial layer 12 and the second epitaxial layer 13. It should be noted that the inward sidewall refers to a decrease in the orthographic projection area or size of the sidewall of the first window 110 on the base 10, in the direction pointing towards the first epitaxial layer 12 from the base 10, in a plane perpendicular to the plane where the base 10 is located. In addition, with a large size of the bottom wall end 110b, the nucleation area of GaN-based materials is large, which makes the growth process easier. In some embodiments, as shown in FIG. 1, the area of the cross-section of the first window 110 in a direction from the base 10 to the opening end 110a gradually decreases, and in this way, the first window 110 has an inward sidewall, thereby reducing dislocation density.

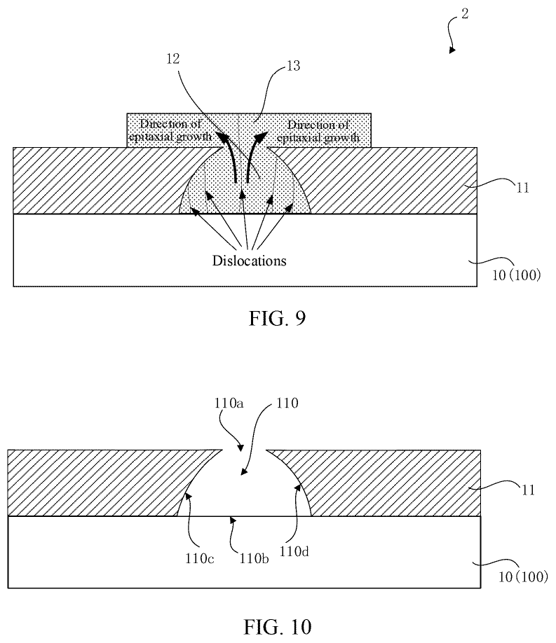

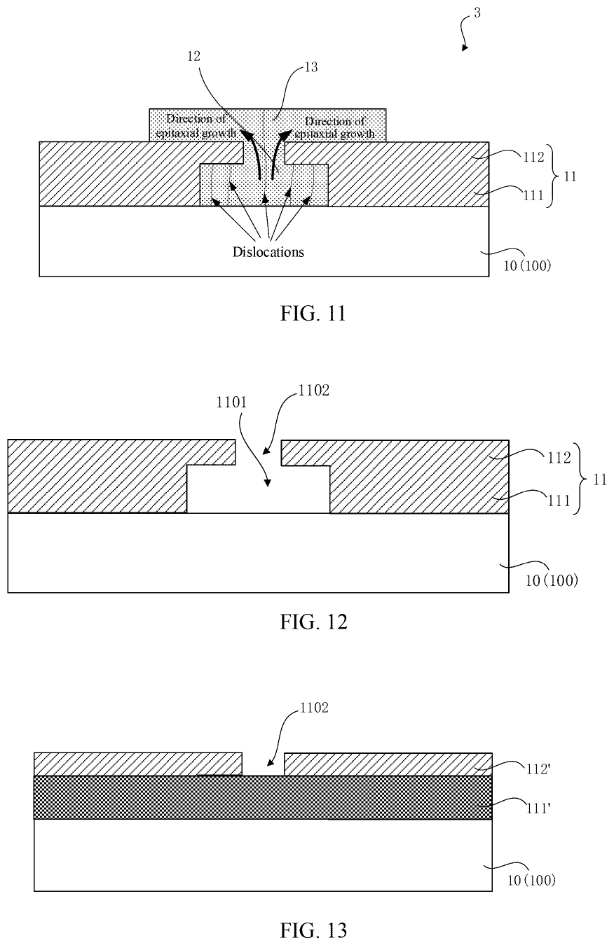

FIG. 9 is a cross-sectional schematic diagram of the semiconductor structure according to a second embodiment of the present disclosure; FIG. 10 is a cross-sectional schematic diagram of a structure of a base and a first mask layer in FIG. 9. As shown in FIGS. 9 and 10, the difference between the semiconductor structure 2 of this embodiment 2 and the semiconductor structure 1 of the embodiment 1 includes that the second side 110c and fourth side 110d of the first window 110 are upward convex curves. In other embodiments, the second side 110c and the fourth side 110d can also be downward concave curves or wavy curves.

In some embodiments, the second side 110c and the fourth side 110d are not curves or straight lines simultaneously.

In some embodiments, when the second side 110c and the fourth side 110d are both straight lines, the three-dimensional structure of the first window 110 can be a prismatic table or a frustum of a cone. When the second side 110c and the fourth side 110d are both curves, the three-dimensional structure of the first window 110 can be a part of a sphere. When the second side 110c and the fourth side 110d are not curves or straight lines simultaneously, the three-dimensional structure of the first window 110 can be any frustum combination of a part of a sphere, a prismatic table, or a frustum of a cone.

In addition to the above differences, other structures of the semiconductor structure 2 in this embodiment 2 can refer to the corresponding structures of the semiconductor structure 1 in the embodiment 1.

Correspondingly, for the manufacturing method, the difference between the manufacturing method of the semiconductor structure 2 in the embodiment 2 and the manufacturing method of the semiconductor structure 1 in the embodiment 1 includes that in step S11, the sixth side 31b and eighth side 31d of the first occupying layer 31 formed by the etching process are curves.

The first occupying layer 31 of the above shape can be achieved by controlling the type of etching gas, the flow rate of the etching gas, or plasma direction during dry etching.

In addition to the above differences, the manufacturing method of the semiconductor structure 2 in the embodiment 2 can refer to the corresponding process steps of manufacturing the semiconductor structure 1 in the embodiment 1.

FIG. 11 is a cross-sectional schematic diagram of a semiconductor structure according to a third embodiment of the present disclosure; FIG. 12 is a cross-sectional schematic diagram of a structure of a base and a first mask layer in FIG. 11. Referring to FIGS. 11 and 12, the difference between the semiconductor structure 3 of the embodiment 3 and the semiconductor structures 1 and 2 of the embodiments 1 and 2 includes that the first mask layer 11 includes a first sub-mask layer 111 close to the base 10 and a second-sub mask layer 112 far from the base 10. The first sub-mask layer 111 has a first sub-window 1101, and the second sub-mask layer 112 has a second sub-window 1102. The second sub-window 1102 and the first sub-window 1101 are interconnected to form at least a part of the first window 110. The area of the orthographic projection of the second sub-window 1102 on the plane where the base 10 is located is smaller than the area of the orthographic projection of the first sub-window 1101 on the plane where the base 10 is located.

The second sub-mask layer 112 can terminate at least some of the dislocations in the GaN-based material grown in the first sub-window 1101, preventing the dislocations from continuing to extend in the second epitaxial layer 13. Therefore, the base 10 with the first mask layer 11 mentioned above can reduce the dislocation density of the first epitaxial layer 12 and the second epitaxial layer 13.

In some embodiments, the materials of the first sub-mask layer 111 and the second sub-mask layer 112 are different.

In addition to the above differences, other structures of the semiconductor structure 3 in this embodiment 3 can refer to the corresponding structures of the semiconductor structures 1 and 2 in the embodiments 1 and 2.

FIG. 13 is a schematic view of an intermediate structure corresponding to a manufacturing method of a semiconductor structure according to the third embodiment of the present disclosure.

Correspondingly, the difference between the manufacturing method of the semiconductor structure 3 in the embodiment 3 and the manufacturing method of the semiconductor structures 1 and 2 in the embodiment 1 and 2 includes that step S1 includes steps S11′ to S13′.

At step S11′, as shown in FIG. 13, a first sub-mask material layer 111′ and a second-sub mask material layer 112′ are sequentially formed on the base 10. The materials of the first sub-mask material layer 111′ and the second sub-mask material layer 112′ are different. In some embodiments, the material of the first sub-mask material layer 111′ can be silicon dioxide, and the material of the second sub-mask material layer 112′ can be silicon nitride, which are respectively formed by physical vapor deposition or chemical vapor deposition. In some embodiments, the aluminum content of the first sub-mask material layer 111′ is lower than that of the second sub-mask material layer 112′.

At step S12′, continuing as shown in FIG. 13, the second sub-mask material layer 112′ is etched to form the second sub-window 1102. The etching process of the second sub-mask material layer 112′ can be dry etching.

At step S13′, as shown in FIGS. 13 and 12, the first sub-window 1101 is formed by laterally etching the first sub-mask material layer 111′ through the second sub-window 1102, and at least part of the first window 110 is composed of the second sub-window 1102 and the first sub-window 1101. The laterally etching for the first sub-mask material layer 111′ can be achieved through wet etching. It should be noted that the wet etching rate of the first sub-mask material layer 111′ is greater than that of the second sub-mask material layer 112′. In some embodiments, the first sub-window 1101 and/or the second sub-window 1102 can also be formed by removing an occupying layer.

In addition to the above differences, the other steps of the manufacturing method of the semiconductor structure 3 in this embodiment 3 can refer to the corresponding steps of the manufacturing method of the semiconductor structures 1 and 2 in the embodiments 1 and 2.

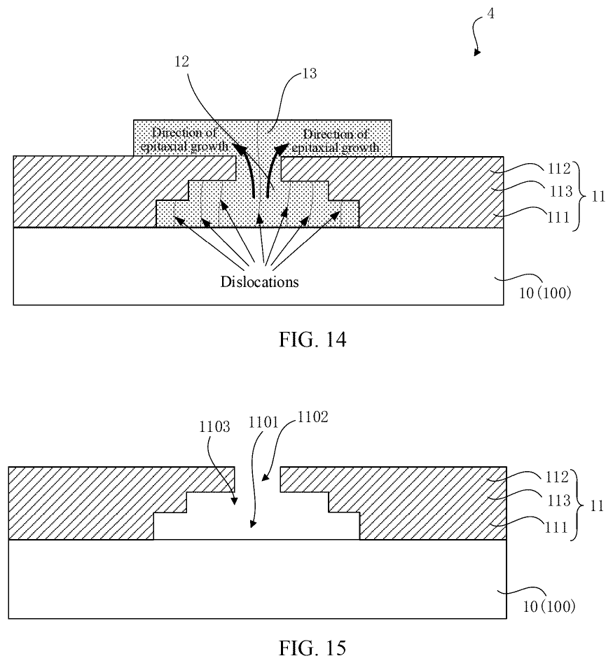

FIG. 14 is a cross-sectional schematic diagram of a semiconductor structure according to a fourth embodiment of the present disclosure; FIG. 15 is a cross-sectional schematic diagram of a structure of a base and a first mask layer in FIG. 14. As shown in FIGS. 14 and 15, the difference between the semiconductor structure 4 of the embodiment 4 and the semiconductor structure 3 of the embodiment 3 includes that the first mask layer 11 also includes a third sub-mask layer 113 located between the first sub-mask layer 111 and the second sub-mask layer 112, and the third sub-mask layer 113 has a third sub-window 1103. The first sub-window 1101, the second sub-window 1102, and the third sub-window 1103 are interconnected to form the first window 110. The area of the orthographic projection of the second sub-window 1102 on the plane where the base 10 is located is smaller than the area of the orthographic projection of the third sub-window 1103 on the plane where the base 10 is located, and the area of the orthographic projection of the third sub-window 1103 on the plane where the base 10 is located is smaller than the area of the orthographic projection of the first sub-window 1101 on the plane where the base 10 is located.

The third sub-mask layer 113 can terminate at least some of the dislocations in the GaN-based material epitaxially grown in the first sub-window 1101, while the second sub-mask layer 112 can further terminate at least some of the dislocations in the GaN-based material epitaxially grown in the third sub-window 1103, making the dislocations unable to continue to extend in the second epitaxial layer 13.

In other embodiments, the first mask layer 11 can also include four or more sub-mask layers. In a direction away from the base 10, the area of the orthographic projection of the window in the upper sub-mask layer on the plane where the base 10 is located is smaller than the area of the orthographic projection of the window in the lower sub-mask layer on the plane where the base 10 is located, so that the upper sub-mask layer can terminate at least some dislocations in the GaN-based material in the window of the lower sub-mask layer. Thus, the dislocation density of the second epitaxial layer 13 is reduced.

In addition to the above differences, the other structures of the semiconductor structure 4 in this embodiment 4 can refer to the corresponding structures of the semiconductor structure 3 in the embodiment 3.

Correspondingly, the difference between the manufacturing method of the semiconductor structure 4 in the embodiment 4 and that of semiconductor structure 3 in the embodiment 3 includes that in step S11′, the first sub-mask material layer 111′, the third sub-mask material layer and the second sub-mask material layer 112′ are sequentially formed on the base 10, and the materials of the first sub-mask material layer 111′, the third sub-mask material layer and the second sub-mask material layer 112′ are different; in step S13′, a third sub-window 1103 is formed by laterally etching the third sub-mask material layer through the second sub-window 1102; the first sub-window 1101 is formed by laterally etching the first sub-mask material layer 111′ through the second sub-window 1102 and the third sub-window 1103.

In addition to the above differences, the other steps of the manufacturing method of the semiconductor structure 4 in the embodiment 4 can refer to the corresponding steps of the manufacturing method of the semiconductor structure 3 in the embodiment 3.

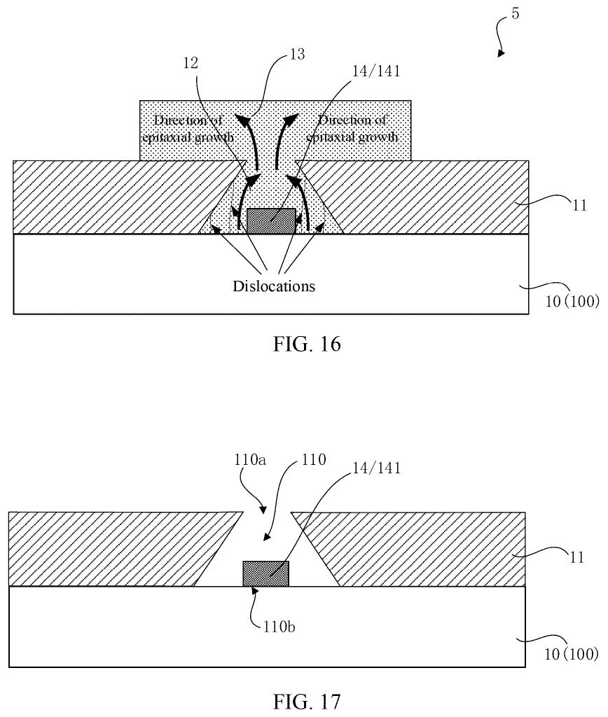

FIG. 16 is a cross-sectional schematic diagram of a semiconductor structure according to a fifth embodiment of the present disclosure; FIG. 17 is a cross-sectional schematic diagram of a structure of a base and a first mask layer in FIG. 16. Referring to FIGS. 16 and 17, the difference between the semiconductor structure 5 of this embodiment 5 and the semiconductor structures 1, 2, 3, and 4 of the embodiments 1 to 4 includes that the semiconductor structure 5 also includes a second mask layer 14, at least including a first region 141, which is located in a part of the bottom wall end 110b; the first epitaxial layer 12 is located on the base 10 and the first region 141.

In this embodiment, the orthographic projection of the opening end 110a on the plane where the base 10 is located falls within the orthographic projection of the first region 141 on the plane where the base 10 is located, in order to further terminate the dislocation of the first epitaxial layer 12 extending in the direction of the thickness of the first mask layer 11 and prevent the dislocations from penetrating through the opening end 110a and extending into the second epitaxial layer 13.

In other embodiments, the orthographic projection of the second mask layer 14 on the plane where the base 10 is located may partially overlap with the orthographic projection of the opening end 110a on the plane where the base 10 is located.

In addition to the above differences, other structures of the semiconductor structure 5 in this embodiment 5 can refer to the corresponding structures of the semiconductor structures 1, 2, 3, and 4 in the embodiments 1 to 4.

Correspondingly, the difference between the manufacturing method of the semiconductor structure 5 in the embodiment 5 and the manufacturing method of the semiconductor structures 2, 3, and 4 in the embodiments 1 to 4 includes that between steps S1 and S2, the second mask layer 14 is deposited before forming the first mask layer 11, where the second mask layer 14 includes the first region 141, which is located in a part of the bottom wall end 110b; in step S2, the epitaxial growth process is performed on the base 10 by using the first mask layer 11 and the second mask layer 14 as masks.

The deposition of the second mask layer 14 can be covered by a mask plate, and the opening of the mask plate corresponds to the opening end 110a of the first window 110. The deposition process can be vertical deposition or inclined deposition. The region covered by the mask plate corresponds to the region where the second mask layer 14 has not been deposited.

In other embodiments, in step S1, before forming the first mask layer 11 on the base 10, a second mask layer 14 can be formed on the base 10; the first window 110 of the first mask layer 11 exposes the base 10 and the second mask layer 14; the epitaxial growth process is performed on base 10 with the first mask layer 11 and the second mask layer 14 as masks. In some embodiments, the orthographic projection of the opening end 110a of the first window 110 on the plane where the base 10 is located falls within the orthographic projection of the pre-made second mask layer 14 on the plane where the base 10 is located.

In addition to the above differences, the other steps of the manufacturing method of the semiconductor structure 5 in this embodiment 5 can refer to the corresponding steps of the manufacturing method of the semiconductor structures 1, 2, 3, and 4 in the embodiments 1 to 4.

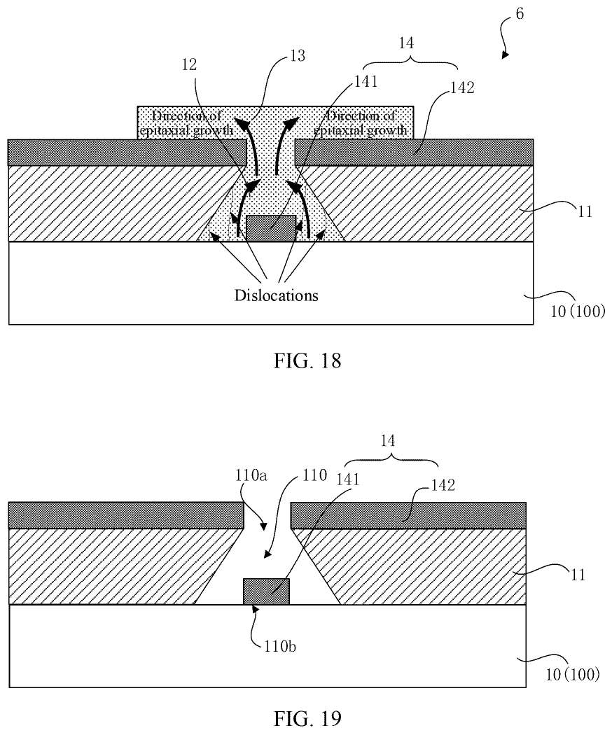

FIG. 18 is a cross-sectional schematic diagram of a semiconductor structure according to a sixth embodiment of the present disclosure; FIG. 19 is a cross-sectional schematic diagram of a structure of a base and a first mask layer in FIG. 18. As shown in FIGS. 18 and 19, the difference between the semiconductor structure 6 of the embodiment 6 and the semiconductor structure 5 of the embodiment 5 includes that the second mask layer 14 includes a first region 141 and a second region 142, where the first region 141 is located in a part of the bottom wall end 110b and the second region 142 is located on the first mask layer 11; and the first epitaxial layer 12 is located on the base 10 and the first region 141.

In this embodiment, the orthographic projection of the opening end 110a on the plane where the base 10 is located falls within the orthographic projection of the first region 141 on the plane where the base 10 is located, in order to further terminate at least some of dislocations of the first epitaxial layer 12 extending in the direction of the thickness of the first mask layer 11 and prevent the dislocations from penetrating through the opening end 110a and extending into the second epitaxial layer 13.

In other embodiments, the orthographic projection of the first region 141 on the plane where the base 10 is located may partially overlap with the orthographic projection of the opening end 110a on the plane where the base 10 is located.

In addition to the above differences, the other structures of the semiconductor structure 6 in this embodiment 6 can refer to the corresponding structures of the semiconductor structure 5 in the embodiment 5.

Correspondingly, the difference between the manufacturing method of the semiconductor structure 6 in the embodiment 6 and that of semiconductor structure 5 in the embodiment 5 includes that the deposition of the second mask layer 14 performed between step S1 and step S2 is a full-surface deposition. Compared to the manufacturing process of the second mask layer 14 in embodiment 5 by using a mask plate, the manufacturing process of the second mask layer 14 in embodiment 6 is full-surface deposition, which is simpler.

The deposition process can be vertical deposition or inclined deposition. When vertically depositing, the orthographic projection of the first region 141 on the plane where the base 10 is located coincides with the orthographic projection of the open end 110a on the plane where the base 10 is located. When depositing in tilt, the orthographic projection of the first region 141 on the plane where the base 10 is located partially coincides with the orthographic projection of the open end 110a on the plane where the base 10 is located.

In addition to the above differences, the other steps of the manufacturing method of the semiconductor structure 6 in the embodiment 6 can refer to the corresponding steps of the manufacturing method of the semiconductor structure 5 in the embodiment 5.

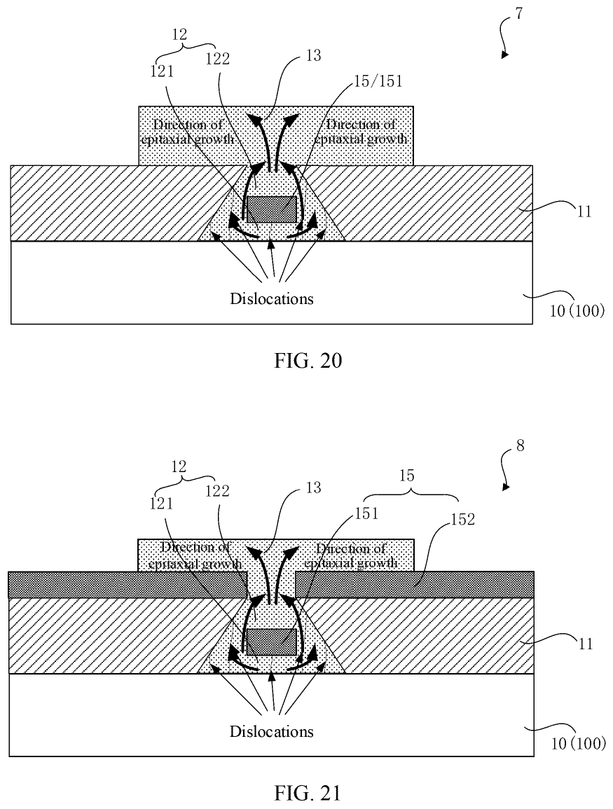

FIG. 20 is a cross-sectional schematic diagram of the semiconductor structure according to a seventh embodiment of the present disclosure. As shown in FIG. 20, the difference between the semiconductor structure 7 of this embodiment 7 and the semiconductor structures 1, 2, 3, 4, 5, and 6 of the embodiments 1 to 6 includes that the first epitaxial layer 12 includes a first sub-epitaxial layer 121 and a second sub-epitaxial layer 122, where the first sub-epitaxial layer 121 is located on the bottom wall end 110b and fills a part of the depth of the first window 110; the semiconductor structure 7 further includes a third mask layer 15, including a third region 151, which is located on a part of the first sub-epitaxial layer 121, and the second sub-epitaxial layer 122 is located on the first sub-epitaxial layer 121 and the third region 151.

In this embodiment, the orthographic projection of the opening end 110a on the plane where the base 10 is located falls within the orthographic projection of the third mask layer 15 on the plane where the base 10 is located, in order to further terminate at least some of dislocations of the first epitaxial layer 12 extending in the direction of the thickness of the first mask layer 11 and prevent the dislocations from penetrating through the opening end 110a and extending into the second epitaxial layer 13.

In some embodiments, the first sub-epitaxial layer 121 can be a nucleation layer, and the base 10 can be at least one of sapphire, silicon carbide, and monocrystalline silicon.

In other embodiments, the orthographic projection of the first region 151 on the plane where the base 10 is located may partially overlap with the orthographic projection of the opening end 110a on the plane where the base 10 is located.

In addition to the above differences, other structures of the semiconductor structure 7 in this embodiment 7 can refer to the corresponding structures of the semiconductor structures 1, 2, 3, 4, 5, and 6 in the embodiments 1 to 6.

Correspondingly, the difference between the manufacturing method of the semiconductor structure 7 in the embodiment 7 and the manufacturing method of the semiconductor structures 1, 2, 3, 4, 5, and 6 in the embodiments 1 to 6 includes that step S2 includes steps S21 to S23.

At step S21, an epitaxial growth process is performed on the bottom wall end 110b to form a first sub-epitaxial layer 121, which fills a part of the depth of the first window 110.

At step S22, a third mask layer 15 is deposited, where the third mask layer 15 includes a third region 151 located on a part of the first sub-epitaxial layer 121.

The deposition of the third mask layer 15 can be covered by a mask plate, and the opening of the mask plate corresponds to the opening end 110a of the first window 110. The deposition process can be vertical deposition or inclined deposition. The region covered by the mask plate corresponds to the region where the third mask layer 15 has not been deposited.

At step S23, epitaxial growth is performed on the first sub-epitaxial layer 121 to form a second sub-epitaxial layer 122 that fills up the first window 110; the second sub-epitaxial layer 122 is located on the first sub-epitaxial layer 121 and the third region 151.

In some embodiments, the orthographic projection of the third region 151 on the plane where the base 10 is located overlaps at least partially with the orthographic projection of the open end 110a on the plane where the base 10 is located.

In addition to the above differences, the other steps of the manufacturing method of the semiconductor structure 7 in this embodiment 7 can refer to the corresponding steps of the manufacturing method of the semiconductor structures 1, 2, 3, 4, 5, and 6 in the embodiments 1 to 6.

FIG. 21 is a cross-sectional schematic diagram of the semiconductor structure according to an eighth embodiment of the present disclosure. As shown in FIG. 21, the difference between the semiconductor structure 8 of the embodiment 8 and the semiconductor structure 7 of the embodiment 7 includes that the third mask layer 15 includes a third region 151 and a fourth region 152, where the third region 151 is located on a part of the first sub-epitaxial layer 121 and the fourth region 152 is located on the first mask layer 11; the second sub-epitaxial layer 122 is located on the first sub-epitaxial layer 121 and the third region 151.

In this embodiment, the orthographic projection of the opening end 110a on the plane where the base 10 is located falls within the orthographic projection of the third region 151 on the plane where the base 10 is located, in order to further terminate at least some of dislocations of the first epitaxial layer 12 extending in the direction of the thickness of the first mask layer 11 and prevent the dislocations from penetrating through the open end 110a and extending into the second epitaxial layer 13.

In other embodiments, the orthographic projection of the third region 151 on the plane where the base 10 is located may partially overlap with the orthographic projection of the opening end 110a on the plane where the base 10 is located.

In addition to the above differences, other structures of the semiconductor structure 8 in this embodiment 8 can refer to the corresponding structures of the semiconductor structure 7 in the embodiment 7.

Correspondingly, the difference between the manufacturing method of the semiconductor structure 8 in the embodiment 8 and that of the semiconductor structure 7 in the embodiment 7 includes that, in step S22, the deposition of the third mask layer 15 is a full-surface deposition. Compared to the manufacturing process of the third mask layer 15 in embodiment 7 by using a mask plate, the manufacturing process of the third mask layer 15 in embodiment 8 is full-surface deposition, which is simpler.

The deposition process can be vertical deposition or inclined deposition. When vertically deposited, the orthographic projection of the third region 151 on the plane where the base 10 is located coincides with the orthographic projection of the open ending 110a on the plane where the base 10 is located. When deposited in tilt, the orthographic projection of the third region 151 on the plane where the base 10 is located partially coincides with the orthographic projection of the open ending 110a on the plane where the base 10 is located.

In addition to the above differences, the other steps of the manufacturing method of the semiconductor structure 8 in the embodiment 8 can refer to the corresponding steps of the manufacturing method of the semiconductor structure 7 in the embodiment 7.

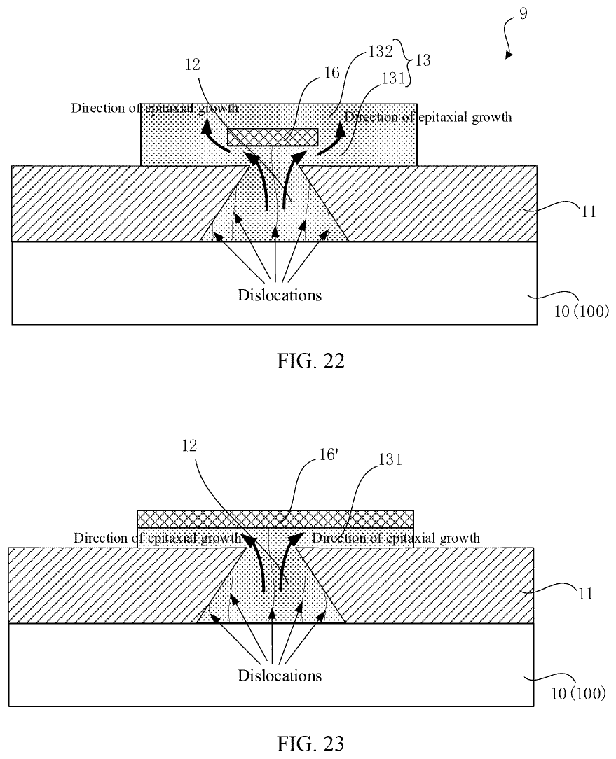

FIG. 22 is a cross-sectional schematic diagram of the semiconductor structure according to a ninth embodiment of the present disclosure. As shown in FIG. 22, the difference between the semiconductor structure 9 of this embodiment 9 and the semiconductor structures 1, 2, 3, 4, 5, 6, 7, and 8 of the embodiments 1 to 8 includes that the second epitaxial layer 13 includes a third sub-epitaxial layer 131 and a fourth sub-epitaxial layer 132; the third sub-epitaxial layer 131 is located on the first epitaxial layer 12 and the first mask layer 11; the semiconductor structure 9 further includes a fourth mask layer 16 located on the third sub-epitaxial layer 131; the orthographic projection of the opening end 110a of the first window 110 on the plane where the base 10 is located falls within the orthographic projection of the fourth mask layer 16 on the plane where the base 10 is located; the fourth sub-epitaxial layer 132 is located on the third sub-epitaxial layer 131 and the fourth mask layer 16.

The fourth mask layer 16 can further terminate at least some of the dislocations extending in the third sub-epitaxial layer 131 in the direction of the thickness of the first mask layer 11, preventing the dislocations from continuing to extend upwards into the fourth sub-epitaxial layer 132.

In addition to the above differences, other structures of the semiconductor structure 9 in this embodiment 9 can refer to the corresponding structures of the semiconductor structures 1, 2, 3, 4, 5, 6, 7, and 8 in the embodiments 1 to 8.

FIG. 23 is a schematic view of an intermediate structure corresponding to a manufacturing method of a semiconductor structure according to the ninth embodiment of the present disclosure.

Correspondingly, the difference between the manufacturing method of the semiconductor structure 9 in the embodiment 9 and the manufacturing method of the semiconductor structures 1, 2, 3, 4, 5, 6, 7, and 8 in the embodiments 1 to 8 includes that in step S21′, referring to FIG. 23, an epitaxial growth process is performed on the first epitaxial layer 12 to form a third sub-epitaxial layer 131; a fourth mask material layer 16′ is formed on the third sub-epitaxial layer 131; as shown in FIG. 22, the fourth mask material layer 16′ is patterned to form a fourth mask layer 16, and the orthographic projection of the open end 110a of the first window 110 on the plane where the base 10 is located falls within the orthographic projection of the fourth mask layer 16 on the plane where the base 10 is located.

In step S22′, as shown in FIG. 22, an epitaxial growth process is performed on the third sub-epitaxial layer 131 to form a fourth sub-epitaxial layer 132, which is located on the third sub-epitaxial layer 131 and the fourth mask layer 16.

In addition to the above differences, the other steps of the manufacturing method of the semiconductor structure 9 in this embodiment 9 can refer to the corresponding steps of the manufacturing method of the semiconductor structures 1, 2, 3, 4, 5, 6, 7, and 8 in the embodiments 1 to 8.

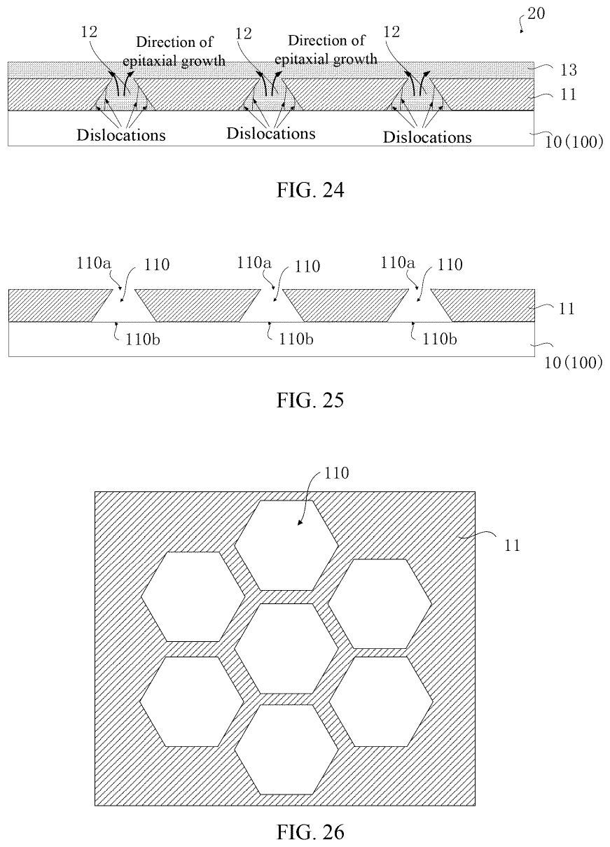

FIG. 24 is a cross-sectional schematic diagram of the semiconductor structure according to a tenth embodiment of the present disclosure; FIG. 25 is a cross-sectional schematic diagram of a structure of a base and a first mask layer in FIG. 24; FIG. 26 is a top view schematic diagram of a structure of a base and a first mask layer in FIG. 24. Referring to FIGS. 24, 25, and 26, the difference between the semiconductor structure 20 and the manufacturing method of the semiconductor structure 20 in the embodiment 10 and the semiconductor structures 1, 2, 3, 4, 5, 6, 7, 8, 9 and their manufacturing method in the embodiments 1 to 9 includes that the there are multiple first windows 110. In some embodiments, the second epitaxial layers 13 corresponding to respective first windows 110 are merged into a plane.

In some embodiments, at least two second epitaxial layers 13 corresponding to at least two first windows 110 are not merged into a plane, for example, there are two independent second epitaxial layers 13 corresponding to two first windows 110, which are two independent structures that are not connected.

As shown in FIG. 26, in this embodiment, the cross-section of each first window 110 is hexagonal, where the cross-section refers to a section parallel to the plane where the base 10 is located. In other embodiments, the cross-section of the first window 110 can also be rectangular, triangular, circular, or other shapes. In some embodiments, when the cross-section of the first window 110 is a polygon, the first window 110 is formed by dry etching with the same number of dry etching times as the number of polygon edges or polygon sides. Alternatively, when the cross-section of the first window 110 is a polygon or a circle, the first window 110 is formed by rotating the dry etching direction, and the angle between the dry etching direction and the plane where the base 10 is located is an acute angle.

GaN-based devices, such as LDs, LEDs, or HEMTs, can be formed on the second epitaxial layer 13.

In addition to the above differences, other structures and process steps of the semiconductor structure 20 in this embodiment 10 can refer to the corresponding structures and process steps of the semiconductor structures 1, 2, 3, 4, 5, 6, 7, 8, and 9 in the embodiments 1 to 9.

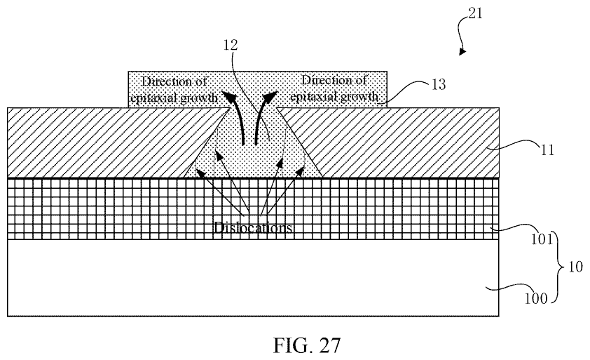

FIG. 27 is a cross-sectional schematic diagram of the semiconductor structure according to an eleventh embodiment of the present disclosure. As shown in FIG. 27, the difference between the semiconductor structure 21 and the manufacturing method of the semiconductor structure 21 in the embodiment 11 and the semiconductor structures 1, 2, 3, 4, 5, 6, 7, 8, 9, 20 and their manufacturing method in the embodiments 1 to 10 includes that, the base 10 includes a semiconductor substrate 100 and a transition layer 101 located on the semiconductor substrate 100. The transition layer 101, the first epitaxial layer 12, and the second epitaxial layer 13 can include the same material or different materials.

The material of transition layer 101 includes, for example, GaN. Compared to without the transition layer 101, directly epitaxially growing the first epitaxial layer 12 and the second epitaxial layer 13 of material AlGaN, InGaN, AlInGaN on sapphire or monocrystalline silicon semiconductor substrate 100, the embodiment 11 can further reduce the dislocation density in the first epitaxial layer 12 and the second epitaxial layer 13.

In addition to the above differences, other structures and process steps of the semiconductor structure 21 in this embodiment 11 can refer to the corresponding structures and process steps of the semiconductor structures 1, 2, 3, 4, 5, 6, 7, 8, 9, and 20 in the embodiments 1 to 10.

Although the present disclosure discloses the above contents, the present disclosure is not limited thereto. One of ordinary skill in the art can make various variants and modifications to the present disclosure without departing from the spirit and scope of the present disclosure. Therefore, the protection scope of the present disclosure should be set forth by the appended claims.

What is claimed is:

1. A semiconductor structure, comprising:
a base; and
a first mask layer, located on the base; wherein the first mask layer has a first window exposing the base, the first window comprises an opening end away from the base and a bottom wall end close to the base; an orthographic projection of the opening end on a plane where the base is located falls within an orthographic projection of the bottom wall end.

2. The semiconductor structure according to claim 1, wherein an area of a cross-section of the first window gradually decreases in a direction from the base to the opening end.

3. The semiconductor structure according to claim 2, wherein a cross-section of the first window perpendicular to the plane where the base is located is enclosed by a first side, a second side, a third side, and a fourth side connected sequentially; the first side corresponds to the opening end, the third side corresponds to the bottom wall end, and the second side and the fourth side correspond to the sidewalls of the first window; the second side comprises a straight line or a curve, and the fourth side comprises a straight line or a curve.

4. The semiconductor structure according to claim 1, wherein the first mask layer comprises a first sub-mask layer close to the base and a second sub-mask layer far from the base, wherein the first sub-mask layer has a first sub-window, and the second sub-mask layer has a second sub-window; the second sub-window and the first sub-window are interconnected and form at least a part of the first window; an area of the orthographic projection of the second sub-window on the plane where the base is located is smaller than an area of the orthographic projection of the first sub-window on the plane where the base is located.

5. The semiconductor structure according to claim 1, further comprising a second mask layer, wherein the second mask layer comprises a first region, and the first region is located on a part of the bottom wall end.

6. The semiconductor structure according to claim 5, wherein an orthographic projection of the first region on the plane where the base is located at least partially overlaps with an orthographic projection of the opening end on the plane where the base is located.

7. The semiconductor structure according to claim 5, wherein the second mask layer further comprises a second region, and the second region is located on the first mask layer.

8. The semiconductor structure according to claim 1, further comprising:
a first epitaxial layer filling up the first window; and
a second epitaxial layer located on the first epitaxial layer and the first mask layer.

9. The semiconductor structure according to claim 8, wherein the first epitaxial layer comprises a first sub-epitaxial layer and a second sub-epitaxial layer, wherein the first sub-epitaxial layer is located on the bottom wall end and fills a partial depth of the first window;
the semiconductor structure further comprises a third mask layer comprising a third region, wherein the third region is located on a part of the first sub-epitaxial layer;
the second sub-epitaxial layer is located on the first sub-epitaxial layer and the third region.

10. The semiconductor structure according to claim 9, wherein an orthographic projection of the third region on the plane where the base is located at least partially overlaps with an orthographic projection of the opening end on the plane where the base is located.

11. The semiconductor structure according to claim 9, wherein the third mask layer further comprises a fourth region; the fourth region is located on the first mask layer; and the second epitaxial layer is located on the first epitaxial layer and the fourth region of the third mask layer.

12. The semiconductor structure according to claim 1, further comprising:
a first epitaxial layer, filling up the first window; and
a second epitaxial layer, located on the first epitaxial layer and the first mask layer;
the second epitaxial layer comprises a third sub-epitaxial layer and a fourth sub-epitaxial layer; the third sub-epitaxial layer is located on the first epitaxial layer and the first mask layer;
the semiconductor structure further comprises a fourth mask layer located on the third sub-epitaxial layer; the orthographic projection of the opening end of the first window on the plane where the base is located falls within an orthographic projection of the fourth mask layer on the plane where the base is located; the fourth sub-epitaxial layer is located on the third sub-epitaxial layer and the fourth mask layer.

13. The semiconductor structure according to claim 1, wherein there are a plurality of first windows, and second epitaxial layers corresponding to the plurality of the first windows are merged into a plane.

14. A manufacturing method of a semiconductor structure, comprising:
providing a base, and
forming a first mask layer on the base, wherein the first mask layer has a first window exposing the base; the first window comprises an opening end far from the base and a bottom wall end close to the base; an orthographic projection of the opening end on a plane where the base is located falls within an orthographic projection of the bottom wall end.

15. The manufacturing method of according to claim 14, wherein forming the first mask layer on the base, comprises:
forming a first mask material layer on the base, wherein in a direction from the base to the first mask material layer, a content of aluminum element of the first mask material layer gradually increases;
etching the first mask material layer to form the first window, such that the first mask material layer becomes the first mask layer.

16. The manufacturing method according to claim 14, further comprising:
before forming the first mask layer, depositing a second mask layer; wherein the second mask layer comprises a first region, and the first region is located on a part of the bottom wall end.

17. The manufacturing method according to claim 14, further comprising an epitaxial growth process;
the epitaxial growth process is performed on the base with the first mask layer as a mask, to sequentially form a first epitaxial layer and a second epitaxial layer, wherein the first epitaxial layer is epitaxial grown from the bottom wall end to fill up the first window, and the second epitaxial layer is epitaxial grown on the first epitaxial layer and the first mask layer.

18. The manufacturing method of according to claim 14, wherein forming the first mask layer on the base, comprises:
forming a first mask material layer on the base;
dry etching the first mask material layer by controlling an etching direction to form the first window, such that the first mask material layer becomes the first mask layer, wherein an angle between the etching direction and a direction from the base to the first mask material layer is an acute angle.

19. The manufacturing method of according to claim 14, wherein forming the first mask layer on the base, comprises:
forming a first occupying material layer on the base;
patterning the first occupying material layer by an etching process to form a first occupying layer, wherein, in a direction from the base to the first occupying layer, an area of a cross-section of the first occupying layer gradually decreases;
forming a first mask material layer on the first occupying layer and the base;
polishing the first mask material layer until the first occupying layer is exposed, such that the first mask material layer becomes the first mask layer; and
removing the first occupying layer to form the first window within the first mask layer.

20. The manufacturing method of according to claim 14, wherein forming the first mask layer on the base, comprises:
forming a first sub-mask material layer and a second sub-mask material layer sequentially on the base;
etching the second sub-mask material layer to form a second sub-window, wherein an etching rate of the second sub-mask material layer is lower than an etching rate of the first sub-mask material layer;
laterally etching the first sub-mask material layer through the second sub-window to form a first sub-window, wherein the second sub-window and the first sub-window form at least a part of the first window.
